(19) United States
(12) Patent Application Publication
(10) Pub. No.: US 2007/0274120 A1
(43) Pub. Date: Nov. 29, 2007

(54) CBRAM cell with a reversible conductive bridging mechanism

(75) Inventors: Cay-Uwe Pinnow, Munchen (DE); Klaus Ufert, Unterschleissheim (DE); Michael Kund, Tuntenhausen (DE)

Correspondence Address: MORRISON & FOERSTER LLP, 1650 TYSONS BOULEVARD, SUITE 400, MCLEAN, VA, 22102, US

(73) Assignee: Infineon Technologies AG, Munich (DE)

(21) Appl. No.: 11/051,483

(22) Filed: Feb. 7, 2005

Related U.S. Application Data
(63) Continuation of application No. 10/834,384, filed on Apr. 29, 2004, now abandoned.

(51) Int. Cl. G11C 11/00

(52) U.S. Cl. 365/148

(57) ABSTRACT

According to the invention CBRAM cell is provided exhibiting a resistive switching effect offering the possibility to store multiple memory states in one cell by programming said memory cell to different resistance levels including at least a first memory state with a high resistance level representing a low-conductivity state of the memory cell and one memory state with a low resistance level representing a high-conductivity state of the memory cell, wherein the resistive switching effect is substantially based on a variation of the concentration of the metallic material incorporated or deposited in the matrix host material.

The invention refers to a memory component using a reversible conductive bridging mechanism. In particular, the invention refers to a memory system, and a process for controlling a memory component to use and to optimize various modes of operation of this memory cell thereby achieving different kinds of memory characteristics on one and the same memory component.

In memory components, in particular, semiconductor memory components, a distinction is made between so-called functional memory components, e.g. PLAs, PALs, etc., and so-called tab memory components, e.g. ROM components (ROM=Read Only Memory), for example PROMs, EPROMs, EEPROMS, and Flash-memories, and RAM components (RAM=Random Access Memory), e.g. DRAMs or SRAMs.

A RAM component is a memory device in which data is stored under a specific address, from which the data can be read out again later. Because a RAM component needs to be provided with as many storage cells as possible, it becomes important for the creation of these cells to be kept as simple and as small as possible.

With so-called SRAMs (SRAM=Static Random Access Memory) the individual memory cells for instance consist of a few, e.g. six transistors, and in so-called DRAMs (DRAM=Dynamic Random Access Memory) of only a single suitably controlled capacitance (e.g. the gate source capacitance of a MOSFET), with which in form of a charge one bit at a time can be stored. In the case of DRAMs, this charge only persists for a short period of time, which means that a so-called “refresh” process must be performed on a frequently basis, e.g. every 64 ms.

In contrast to this, in the case of SRAMs, the charge does not need to be refreshed, i.e. the respective data remains stored in the cell as long as a respective supply voltage is fed to the SRAM. ROM components (ROM=Read Only Memory), for example PROMs, EPROMs, EEPROMs, and Flash-memories, are memory components on which the respective data remains stored even after the respective supply voltage is turned off.

In general and during the normal use of a ROM component, no write operations but only read operations are performed. In order to write data onto ROMs, e.g. PROMs, EPROMs, EEPROMs, i.e. in order to program the ROM, in many cases special instruments have to be used. Just as is the case for RAMs, the typical read access times, and the times it takes to write data onto the ROMs may differ between the different types of ROMs.

Due to the above-mentioned differences between e.g. RAM and ROM memory components and due to the differences mentioned between the different types of RAMs and ROMs (and due to further differences not mentioned herein), depending on the particular memory characteristics needed for a particular application, the particular memory component which best fulfills the specific needs of a specific application is usually chosen for the particular application.

In case two or more different memory characteristics are necessary for one and the same application, two or more different types of memory components have to be used, increasing the size, the complexity and the costs of the application.

The majority of nonvolatile memories is based on charge storage and these devices are fabricated from materials available in CMOS processes. However, these memory concepts based on charge storage have some general drawbacks like high voltage operation (10-20V), slow programming speed (between μs to ms) and a limited programming endurance (typically 10⁵-10⁶ write/erase cycles). Due to the required high voltages a high power consumption is characteristic for programming and erasing FLASH memories.

These shortcomings are caused by the requirement of long term data retention, which necessitates the existence of a large energy barrier that has to be overcome during programming and erasing the memory cell. The existence of such an energy barrier thus severely limits the performance and the scalability of these devices. These backlashes imply several severe restrictions regarding the system design. Thus, the major advantage of FLASH memory is its nonvolatility and its small cell size making them well suited for high density memories combined with low manufacturing costs per bit. In addition to the memory components mentioned above so-called programmable metallization cell (PMC) memory components are known in the art. In a PMC memory cell, during the programming of the cell, a metallic dendrite between respective electrodes—depending on whether a logic “1”, or a logic “0” shall be written into the cell—is either built up, or dissolved. Thus, the contents of the PMC memory cell is defined by the respective resistance between the electrodes.

The resistance between the electrodes is controlled by suitable current or voltage pulses applied to electrodes arranged at the PMC memory cell, thereby causing suitable electrochemical reactions which lead to the building up or dissolution of the above-mentioned metallic dendrite between the electrodes. Such programmable metallization cells (PMC) comprise a layer of so-called chalcogenide material enriched with e.g. Ag—As(Ge)—Se or Ag—As(Ge)-S which is capable of electrochemical reactions due to externally applied voltage or current pulses, thereby shorting the electrical resistance of the chalcogenide material layer and changing the resistance of the entire PMC memory cell.

PMC memory cells are e.g. disclosed in Y. Hirose, H. Hirose, J. Appl. Phys. 47, 2767 (1975), M. N. Kozicki, M. Yun, L. Hilt, A. Singh, Electrochemical Society Proc., Vol. 99-13, (1999) 298, and e.g. in M. N. Kozicki, M. Yun, S. J. Yang, J. P. Aberouette, J. P. Bird, Superlattices and Microstructures, Vol. 27, No. 5/6 (2000) 485-488, as well as in M. N. Kozicki, M. Mitkova, J. Zhu, M. Park, C. Gopalan, “Can Solid State Electrochemistry Eliminate the Memory Scaling Quandry”, Proc. VLSI (2002), and in R. Neale: “Micron to look again at non-volatile amorphous memory”, Electronic Engineering Design (2002), etc., the contents of these documents being incorporated herein by reference.

For applications in which a fast memory switching and a high switching endurance is required DRAM chips or SRAM chips are commonly used. DRAM can support high data transmission rates combined with a relatively small cell size thus making it an attractive candidate for commodity products.

Especially for future mobile applications, low power consumption, nonvolatility and high operation speed enabling fast data rates, are mandatory. Since charge storage memories (e.g. DRAM and floating gate memories like FLASH) are reaching their scaling limits due to data retention problems caused by inevitable charge leakage from the cells, and moreover, poor data sensing capability of the ever decreasing amounts of stored charge, alternative electronic switching mechanisms seem superior to meet the above mentioned requirements.

Therefore, one object of the present invention is to develop a nonvolatile memory cell, which is based on a fast, scalable, low voltage switching mechanism including temperature stability and a high switching endurance. Another object of the present invention is to provide a memory concept capable of operating at low programming voltages, e.g. less than 1 V, which can reach switching times in the submicrosecond area. Moreover, the present invention is aimed to provide a novel memory system, and novel process for controlling a memory component, in particular, a process which allows to achieve different kinds of memory characteristics on one and the same memory component. Still another object of the present invention is to use and to optimize various modes of operation of said memory cell concept, so that DRAM and nonvolatile specifications can be fulfilled simultaneously.

These and other objects are achieved by means of the subject matters of appended independent claims 1, 4, 23, 24 and 26. Further advantageous features of the invention are stated in the appended dependent claims.

According to one aspect of the invention a CBRAM memory cell is provided comprising a matrix host material and metallic material incorporated or deposited therein, the memory cell exhibiting a memory switching mechanism substantially based on a variation of the concentration of the metallic material incorporated or deposited in the matrix host material.

According to another aspect of the invention a CBRAM memory cell is provided exhibiting a resistive switching effect offering the possibility to store multiple memory states in one cell by programming said memory cell to different resistance levels including at least a first memory state with a high resistance level representing a low-conductivity state of the memory cell and one memory state with a low resistance level representing a high-conductivity state of the memory cell, wherein the resistive switching effect is substantially based on a variation of the concentration of the metallic material incorporated or deposited in the matrix host material.

According to still another aspect of the invention a process for controlling a memory component including a CBRAM memory cell according to one of the preceding claims, comprising the step of using various operation modes to operate the CBRAM memory cell, in particular an operation mode for long data retention, or an operation mode for fast switching between different memory states of said memory cell.

The proposed new memory concept offers the possibility to store even multiple memory states in one cell by programming this new memory cell to various resistance levels (Multi-Level-Cell). This nonvolatile switching mechanism exhibits a good scalability to extremely small feature sizes thus enabling higher bit density. The novel memory concept is capable of operating at low programming voltages, e.g. less than 1 V, and can reach submicrosecond switching times. Moreover, the nonvolatility of the proposed memory concept makes it attractive as an universal memory thus offering a broad range of various applications.

In addition, it is possible to optimize and to use various modes of operation of this memory cell concept, e.g. optimize it for long data retention, or for fast switching etc., so that DRAM and nonvolatile specifications can be fulfilled simultaneously. Furthermore, by optimizing this new memory concept, various features can be used on one chip or in one package.

As another advantage of the present invention it can be avoided that—instead of one single memory component—two or more memory components of different types have to be used. Therefore, the size, the complexity, and the costs of the system can be reduced.

The memory switching mechanism according to the present invention is substantially based on a variation of the concentration of metallic material incorporated in a matrix host material, which can be a chalcogenide glass for example. The resistivity of the matrix can vary over orders of magnitudes from a high resistivity at room temperature (i.e. exhibiting an insulating or semiconducting behaviour) to low resistivity values, which are lower by several orders of magnitude. This huge resistance change is caused by local variations of the chemical composition on a nanoscale structure. The glassy materials are deposited far away from their thermal equilibrium condition, which makes them sensitive to chemical and structural fluctuations on atomic scale. However, these fluctuations do not have an impact on the macroscopic memory state of the switching device.

Based on a matrix having a variable amount of metallic atoms together with cluster-like amorphous or nanocrystalline aggregates a large resistance switching behaviour can be attained. The variation of the total amount and/or size of the precipitations being present in this matrix enables a fast modification of the physical and especially of the electric properties. For chalcogenide based matrix films, the metallic solubility is very high so that large amounts of up to 70% of metal can be incorporated into the film. This doping can be attained by various methods, e.g. UV light stimulated doping, thermal doping, implantation, electrical forming, etc. The nanostructure of the host matrix is thus heterogeneous in terms of chemical composition and electric properties.

In contrast to the state of the art resistive switching mechanism, the resistive switching mechanism according to the present invention is not based on the formation of a dendritic pathway, but rather on the statistical bridging of multiple metal rich precipitates. Upon continued application of a write pulse to the conductive bridging cell (CB-cell) said precipitates grow in density until they eventually touch each other, forming a conductive bridge through the entire CB-cell which results in a highly conductive, metallic connection between the two electrodes of the CB-cell. This corresponds to a percolation mechanism including the conductive bridging of precipitates, which are present in the matrix film, leading to an electrical bridging of the electrodes by a highly conductive connection. Due to the aforementioned statistical fluctuations in the matrix, this linking electrical bridge can change from one switching event to the next, which is comparable to a random network linking via different nanostructural precipitations.

This means that the described conductive bridging mechanism is temporary for the duration of being switched on. However, the bridging mechanism can be sustained for long storing times, so that the nonvolatility of the state can be guaranteed. Besides the existence of these precipitates there are also metallic, semiconducting or ionic constituents present in the matrix, which are free to move in the matrix. This movement can be stimulated, for example, by applying external electric fields to the matrix, so that an electrically induced ion drift occurs.

Electrically induced movement offers the advantage that reversible concentration changes can be obtained simply by driving in and pulling out these mobile metal ions. Caused by the mobility of these metallic or ionic components an increase or a decrease in number and/or size of the metal rich precipitates can occur. The bridging is attained by growing of the dimensions and/or increasing the number of the metal rich clusters which narrows the inter-precipitate distance, so that a percolation like mechanism takes place. In this way the isolated precipitates get in contact with each other and thus form a conductive bridging through the formerly low-conductive matrix representing the high-conductivity or ON state of the film.

A preferred embodiment of this invention is achieved by forming a first electrode of a semiconducting or a metallic material, which does not show a significant solubility nor a significant mobility to penetrate into or mix up with the matrix material. The chalcogenide matrix material is in direct contact with the first electrode. Another second electrode, which is also in direct contact with the matrix material exhibits the required solubility and the required high mobility within the matrix. Both electrodes do not have a direct electrical contact nor interface with each other, so that the chalcogenide matrix material separates the two electrodes. The arrangement of these electrodes can be, for example, vertical or horizontal in order to form the described conductive bridging memory cell (CBRAM cell).

Said electrodes are in direct contact to other conducting or doped semiconducting materials (e.g. metals wires or metal plugs) to electrically connect the CBRAM cell to other devices, e.g. transistors or other CBRAM cells. In another preferred embodiment one electrode of the aforementioned CBRAM cell is in contact to the Source/Drain region of a select transistor, which can be manufactured in a semiconducting substrate, e.g. silicon substrate, resulting in the formation of a 1T/1R CBRAM unit cell. The transistor is used for selecting the CBRAM cell by activating the Wordline of the transistor and thus passing a read/write/erase current through the Source-Drain region of it. Other implementations of a CBRAM cell would be to arrange them in a matrix array or in a matrix array including a diode.

Details of the present invention will be more fully understood when considered with respect to the following description, appended claims and accompanied drawings, wherein:

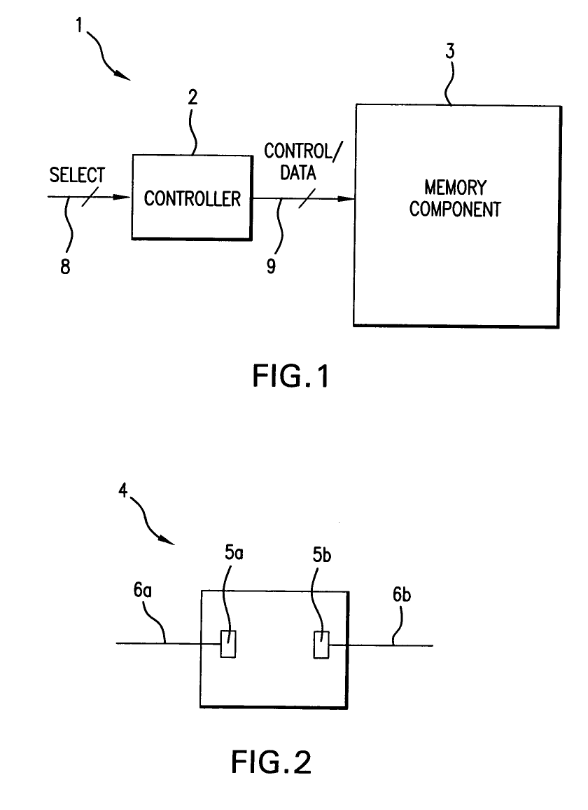

FIG. 1 is a simplified, schematic block diagram of an exemplary memory system with a controller and a memory component including a CBRAM memory cell according to the present invention;

FIG. 2 is a simplified, schematic block diagram of one of the several CBRAM memory cells of the memory component shown in FIG. 1;

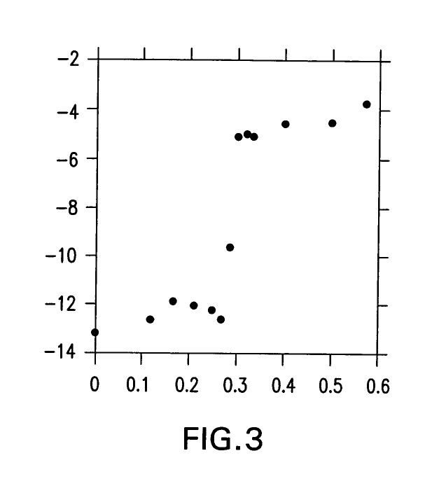

FIG. 3 shows a diagram referring to the threshold transition of a metal doped matrix sample usable in a CBRAM memory cell according to the present invention;

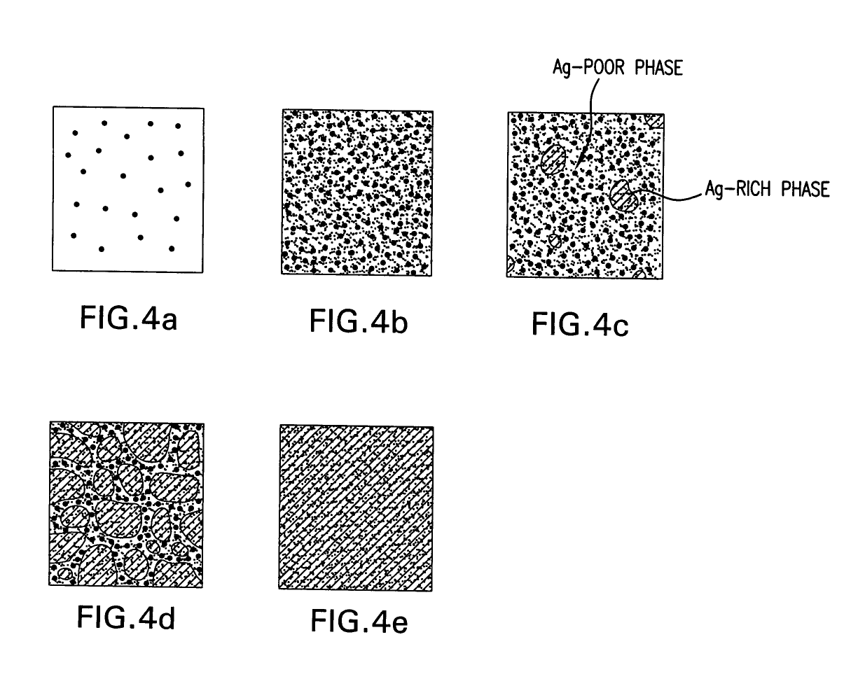

FIG. 4 is a schematic illustration of the change in the structure of S- and Se-based films with an increase in Ag content usable in a CBRAM memory cell according to the present invention;

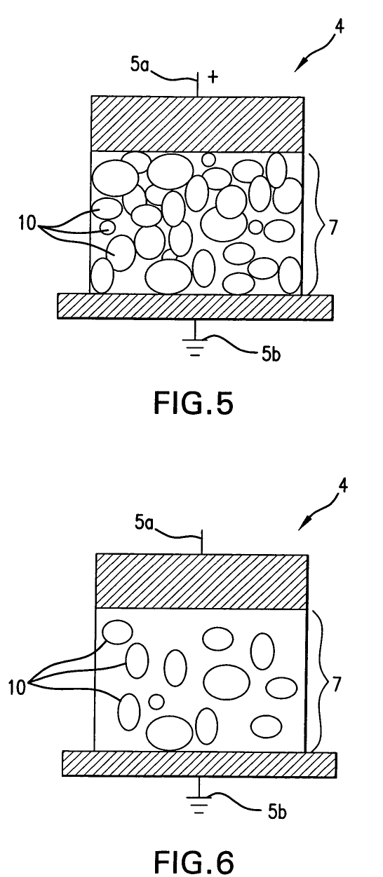

FIG. 5 shows a schematic CBRAM memory cell according to a preferred embodiment of the present invention in an ON state; and

FIG. 6 shows a schematic CBRAM memory cell according to a preferred embodiment of the present invention in an OFF state.

FIG. 1 shows a simplified, schematic block diagram of an exemplary memory system 1, with a controller 2 and a memory component 3 including a CBRAM memory cell according to the present invention.

The controller 2 may be built in form of a component which is separate from the memory component 3, or—alternatively—the controller 2 and the memory component 3 may be built on one and the same semi-conductor component. The memory component 3 may include a CBRAM memory cell or component in accordance with the present invention.

In the memory component 3—after a corresponding address was applied to respective address pins or address input pads (not shown) of the memory component 3 or of the respective semi-conductor component additionally comprising the controller 2—data may be stored under the respective address, and may later on be read out again under this address. For inputting and outputting of the data, data pins, or data input/output pads (I/Os or Input/Outputs, respectively) are provided, e.g. 16 data pins (e.g. on the memory component 3, or the respective semiconductor component additionally comprising the controller 2).

By applying a corresponding signal (e.g. a read/write signal) to a write/read selection pin or pad, respectively, which is not illustrated here, it can be selected whether data is to be stored in, or to be read out of the memory component 3. The data input into the memory component 3 is stored there in corresponding memory cells as defined by the above address, and can later on be read out again from the corresponding memory cells.

The memory cells can be CBRAM memory cells 4 according to a preferred embodiment of the invention. The CBRAM memory cells may have a cell size of e.g. 1 μm×1 μm, or 0.5 μm×0.5 μm or a bigger or smaller size, e.g. smaller than 100 nm×100 nm.

A CBRAM memory cell 4 comprises two or more electrodes 5a, 5b, used as e.g. anode(s) and cathode(s), as shown in FIG. 2.

During the programming of the CBRAM cell 4, i.e. the storing of data in the cell 4, a resistive bridging mechanism as described herein takes place. Due to the resistive bridging mechanism a metallic or semiconducting connection/clusters between electrodes 5a, 5b is either built up, or dissolved depending on whether a logic “1”, or a logic “0” shall be written into the cell 4.

Hence, the contents of the respective memory cell 4 is defined by the respective resistance between the electrodes 5a, 5b, which can be measured via respective lines 6a, 6b connected with the respective electrodes 5a, 5b, e.g. by use of the lines 6a, 6b applying a voltage between the electrodes 5a, 5b, and measuring whether or not a current or a current above a predetermined value then flows between the line 6a, the electrode 5a, and the electrode 5b, and the line 6b).

The resistance between the electrodes 5a, 5b is controlled by suitable programming pulses (write pulses or erase pulses) on respective control lines connected with the CBRAM memory cell 4 (in the case shown in FIG. 2, the lines 6a, 6b connected with the electrodes 5a, 5b), thereby causing the described electrochemical reactions which lead to the building up, or dissolution of the above-mentioned metallic clusters between the electrodes 5a, 5b, as described in the present specification. As a metal for the metallic or semiconducting connection, any suitable metal may be used, e.g. copper (Cu) or e.g. silver (Ag), etc.

A large number of the above memory cells 4 is arranged—in the form of respective rows and columns—in one or more rectangular or square arrays, so that e.g. 32 MBit, 64 MBit, 128 MBit, 256 MBit, 512 MBit, or 1024 MBit (1 Gbit), etc. of data can be stored in a respective array depending on the number of memory cells 4 contained therein.

The memory system 1 comprising the memory component 3, and the controller 2 is connected to one or more devices (not shown), e.g. one or several processors, or other semi-conductor devices, etc., which—under control of the controller 2—make use of the memory component 1 to store data therein, and to read out the stored data.

The device or devices, e.g. processor or processors, are connected to the memory system 1, e.g. the controller 2 and/or the memory component 3, via several lines (e.g. being a part of or being connected with a bus system), e.g. several address and/or data and/or read/write selection lines, etc., which e.g. may be connected with the above address pins and/or data pins, and/or the above read/write selection pin, etc.

Additionally, as shown in FIG. 1, the processor or processors may be connected to the memory system 1, e.g. the controller 2 and/or the memory component 3, via one or more separate memory system mode selection lines 8, which can be as well a part of or being connected with the bus system mentioned above.

A respective signal (here: a memory system mode selection signal (SELECT-Signal)) put out by the device or the devices on the memory system mode selection lines 8 is transmitted to the controller 2, so as to select one of several possible memory modes, e.g. a “soft writing mode”, a “non-volatile writing mode” or a “hard writing mode”, etc. for the memory system 1. Preferably, the data to be stored in the memory system 1 are transmitted to the memory system 1 on the respective data lines simultaneously or shortly after the respective SELECT-Signal. The respective memory modes might be encoded in the SELECT-Signal by specific codes.

After the respective memory mode has been indicated, the controller 2 controls the storage of the data on the memory component 3 in accordance with the selected memory mode by sending out corresponding control and/or data signals on respective control and/or data lines 9 to the memory component 3. This is done by suitably adjusting the duration and/or the intensity and/or the number of programming pulses applied on respective (control) lines 6a, 6b connected with the memory cell 4 on which the data is to be stored.

When for instance a “soft writing” is to be performed, one or more relatively short programming pulses of a relatively low intensity is/are applied to the respective memory cell 4. For this sake e.g. one or several pulses with a current intensity between about 10 nA and 10 μA, in particular between about 100 nA and 5 μA, with a current intensity of e.g. 2 μA, and a duration between about 50 ns and 200 μs, in particular e.g. 1 μs are applied to the respective memory cell 4.

Further, when a “non-volatile writing” is to be performed, one or more pulses of medium intensity and a medium duration is/are applied to the respective memory cell 4 (e.g. one or several pulses with a current intensity between about 5 μA and 50 μA, in particular between about 20 μA and 40 μA, e.g. with a current intensity of 25 μA, and a duration between about 100 ns and 500 μs, in particular 20 μs).

In addition, when a “hard-writing” is to be performed, one or more relatively long programming pulses of a relatively high intensity is/are applied to the respective memory cell 4 (e.g. one or several pulses with a current intensity between about 20 μA and 150 μA, in particular with a current intensity higher than 50 μA, e.g. 80 μA, and a duration between about 1 μs and is, in particular 100 μs).

In other words, whether a “soft writing”, a “non-volatile writing”, or a “hard-writing” are performed on a CBRAM memory cell, it depends on the amount of charge that flows, i.e. the product of the above current intensity, and the (total) duration of the applied pulse(s). The above mentioned values for the current, and the (total) duration of the applied pulses refer to a cell size of about 1 μm×1 μm. If different cell sizes are used, correspondingly amended values for the current intensity, and the (total) duration of the applied pulses shall be used.

When a “soft writing” is performed, and one or more of the above relatively short programming pulses is/are applied to the respective memory cell 4, only a small amount of metal is precipitated/plated out in the memory cell 4 due to the shortness and/or weakness of the respective electrochemical reactions caused by the pulse/pulses.

When a “non-volatile writing” is performed, and one or more of the above programming pulses of medium intensity and medium duration is/are applied to the respective memory cell 4,—due to the higher amount of charge transported, i.e. the higher migration amount of metal ions into the host material matrix—more metal is precipitated/plated out in the chalcogenide material of the memory cell 4 than is the case in the “soft writing mode”. Due to the higher amount of metal precipitated/plated out in the memory cell 4, the respective data remains stored in the memory cell for a relatively long period of time (e.g., between 1 month and several years, in particular, between 1 year and 20 years, e.g. 10 years, etc.).

Still, the amount of metal precipitated/plated out in the memory cell 4 is low enough to allow new data to be written on the memory cell 4 whenever appropriate, thereby erasing the old data. Therefore, in this mode (“non-volatile writing mode”), the memory component (or parts thereof) may be used as non-volatile memory, e.g. as non-volatile memory for the above processor(s) or other electronic devices.

In contrast thereto, when a “hard writing” is performed, and one or more of the above programming pulses of the above high intensity and high duration is/are applied to the respective memory cell 4,—due to the even higher amount of charge transported, i.e. the even higher amount of metal ion migration into the host material matrix—even more metal is precipitated/plated out in the chalcogenide material of the memory cell 4 than is the case in the “non-volatile writing mode”.

The respective data stored in the memory cell 4 by the above “hard writing process” is non-erasable (“one-time writing”), i.e. the data cannot be changed in future cycles.

This is because in the case of a hard-written “1” (i.e., a metallic connection being present between the electrodes 5a, 5b) during the “hard writing” the cathode of the memory cell 4 is flooded by/overflown with elementary metal. When it is later on tried to erase the data, the respective current is constantly lead over a metallic path in form of a stream of electrons. Hence, no metal is dissolved, and the data remains stored. Furthermore, in the “hard writing mode”, during the “hard-writing” of a “1”, metal is deposited on the anode, which leads to the two electrodes 5a, 5b then essantially being reactively symmetric, avoiding that a hard-written “1” may be changed in future cycles.

Therefore, in the above “hard writing mode”, the memory component (or parts thereof) may be used as a One Time Programmable Memory, e.g. as One Time Programmable Memory for the above processor(s) or other electronic devices, e.g. to (non-erasably) store program code, serial numbers, cryptographic keys, etc. or other security-relevant data. The specific use of the memory component 3 as e.g. working memory, Non Volatile Memory or One Time Programmable Memory, etc. might hence be flexibly chosen during operation. Thus, it can be avoided that—instead of the memory component 3 including a CBRAM memory cell according to the present invention—two or more memory components of different types have to be used. Thereby, the size, the complexity and the costs of the memory system can be reduced.

FIG. 3 shows a diagram referring to the threshold transition of a metal doped matrix sample usable in a CBRAM according to the present invention. In particular, FIG. 3 shows the threshold transition of said metal doped matrix sample from a low-conductive state to a highly conductive state depending on the silver content x. In FIG. 3, the x-coordinate shows the transition threshold and the y-coordinate shows the logarithm of the electrical conductivity of the sample. The transition threshold depends on the matrix materials used, its composition, vacancy concentration, etc. It can be seen from FIG. 3 that the electrical conductivity of the sample changes by about 7 orders of magnitude.

FIG. 4 is a schematic illustration of the change in the structure of S- and Se-based films with an increase in metal content (e.g. Ag, Cu, Zn, . . . ) usable in a CBRAM according to the present invention. As can be seen from FIG. 4 the metal content in the structure of S- and Se-based films increases from FIG. 4(a) to (e). The small dots in FIG. 4(a)-(d) display schematically the metal concentration, i.e. a high number of dots represents a high density and means a high metal concentration. The metal concentration of the metal-rich phase (hatched area) is close to the maximum Ag concentration

FIG. 4, especially the FIG. 4(c) and the FIG. 4(d), shows metal rich precipitates which are distributed within the host material matrix or chalgonide material matrix. In FIGS. 4(a) and (b), initial stages of the matrix during the doping process with metal are shown. In FIG. 4(c) metal rich precipitates were formed due to a large metal concentration in the matrix. These metal-rich precipitations are clearly separated, whereas in FIG. 4(d) the densely localised precipitates are close to the percolation threshold. FIG. 4(e) demonstrates the case of a complete saturation of the matrix by the doping metal and creates an over-programming of the memory cell which can be used in the above mentioned “hard writing mode”.

In more detail, FIG. 4 shows a schematic illustration of a phase separation model. FIG. 4(a) shows the films with low metal concentration, the small dots schematically represent the metal concentration and do not signify phase separation. FIG. 4(b) shows the films completely comprising the metal-poor phase. FIG. 4(c) shows the phase-separated films, wherein the metal-poor phase is present to a greater extent than the rich phase.

FIG. 4(d) shows the phase-separated films with a higher metal concentration than shown in FIG. 4(c). The metal-rich phase is dominant with respect to the metal-poor phase at this stage. FIG. 4(e) represents the films completely comprising the metal-rich phase (maximum metal content).

FIG. 5 shows a schematic CBRAM memory cell according to a preferred embodiment of the present invention in an ON state. The CBRAM memory cell shown in FIG. 5 includes a layer 7 of chalcogenide material representing the host material matrix. This chalcogenide glass host 7 is preferably made of GeSe, GeS, SiSe, SiS, and/or AgSe or Ag—S The CBRAM memory cell further comprises two electrodes 5a and 5b attached to and in electrical contact with the chalcogenide layer 7. Electrical current or voltage pulses can be applied to the chalcogenide material layer 7 via the electrodes 5a and 5b.

A first electrode 5a, which is also in direct contact with the matrix material layer 7, is formed of a material with the required solubility and the required high mobility within the matrix. Therefore, the first electrode 5a is made of, e.g. Cu, Ag, Au or Zn, so as to function as an ion donor for the matrix material layer 7. The second electrode 5b is formed of a semiconducting or a metallic material, which does not show a significant solubility nor a significant mobility to penetrate into or mix up with the matrix material layer 7. Therefore, the second electrode 5b is made of an inert material, e.g. W, Ti, Ta, TiN, Pt or doped Si, TaN, AL.

The chalcogenide matrix material layer 7 is in direct contact with both electrodes 5a and 5b, whereas both electrodes 5a and 5b do not have a direct electrical contact nor interface with each other, so that the chalcogenide matrix material layer 7 separates the two electrodes 5a, 5b. The arrangement of these electrodes 5a, 5b can be vertical or horizontal to form the described or conductive bridging memory cell (CBRAM or CB cell) 4.

Furthermore, said electrodes 5a and 5b are in direct contact to metals wires or metal plugs (not shown) to electrically connect the CBRAM cell to other devices, e.g. transistors or other CBRAM cells.

The chalcogenide material layer 7 includes metallic material incorporated in the matrix host material, the atoms of the metallic material are deposed in the matrix host material in metal rich precipitations 10, i.e. cluster-like amorphous or nanocrystalline aggregates. The memory switching mechanism of the CBRAM memory cell 4 according to the present invention is substantially based on a variation of the concentration of the metallic material 10 incorporated in a matrix host material 7.

As described above the resistivity of the matrix 7 can vary over orders of magnitudes from a high resistivity (i.e. exhibiting an insulating or semiconducting behavior) to low resistivity values, which are lower by several orders of magnitude. This huge resistance change is caused by local variations of the chemical composition of the chalcogenide matrix 7 on a nanoscale structure.

Based on a matrix 7 having a variable amount of metallic atoms together with cluster-like amorphous or nanocrystalline aggregates 10 a large resistance switching behaviour of the CB cell 4 can be attained. The variation of the total amount of precipitations 10 being present in said matrix 7 enables a fast modification of the physical and especially of the electrical properties of the CBRAM cell 4. The doping of up to 70% of metal into the chalcogenide matrix layer 7 can be attained for instance by UV light stimulated doping, thermal doping, implantation, electrical forming, etc. The nanostructure of the host matrix 7 is thus heterogeneous in terms of chemical composition and electric properties.

The resistive switching mechanism according to the present invention is not based on the formation of dendritic pathways, but rather on the statistical bridging of multiple metal rich precipitates 10 within the chalcogenide material layer 7. Upon continued application of a write pulse to the conductive bridging cell (CB-cell) 4 said precipitates 10 grow in density until they eventually touch each other, forming a conductive bridge through the entire CB-cell 4 which results in a highly conductive, metallic connection between the two electrodes 5a and 5b of the CB-cell 4. This situation represents a high-conductivity or on state of the programmable metallization memory cell.

Said effect corresponds to a percolation mechanism including the conductive bridging of precipitates 10, which are present in the matrix film 7, leading to an electrical bridging of the electrodes 5a and 5b by a highly conductive connection. This means that the described conductive bridging mechanism is temporary for the duration of being switched on. As described above, said conductive bridging mechanism can also be sustained for long storing times, so that the nonvolatility of the respective state can be guaranteed.

Besides the existence of these precipitates there are also metallic, semiconducting or ionic constituents present in the matrix, which are free to move in the matrix. This movement can be stimulated, for example, by applying external electric fields to the matrix, so that an electrically induced ion drift occurs.

Electrically induced movement offers the advantage that reversible concentration changes can be obtained simply by driving in and pulling out these mobile metal ions. Caused by the mobility of these metallic or ionic components an increase or a decrease in size and/or number of the metal rich precipitates 10 can occur. The movement of mobile metal ions into the chalcogenide host material layer 7 can also be obtained by a redox reaction that drives the metal ions from the reactive electrode 5a into the chalcogenide glass 7.

The bridging is attained by growing the number and/or growth of the dimensions of the metal rich clusters 10 which narrows the inter-precipitate distance, so that a percolation like mechanism takes place. Thus, metal rich clusters 10 form leading to a percolative bridging. Once a sufficient metal concentration in the chalcogenide glass 7 is reached, a conductive bridging between the top electrode 5a and the bottom electrode 5b is formed, which results in the desired circuit connection. In this way the isolated precipitates 10 get in contact with each other and thus form a conductive bridging through the formerly low-conductive matrix 7 representing the high-conductivity or ON state of the CB memory cell 4.

FIG. 6 shows a schematic CBRAM according to a preferred embodiment of the present invention in an OFF state. Pulling out said mobile metal ions from the chalcogenide host material layer 7 causes a decrease in number and/or size of the metal rich precipitates 10 in the chalcogenide glass 7. Thus, the electrical bridging is reduced by broadening the inter-precipitate distance. In this way the isolated precipitates are not in contact with each other any more and do not provide a conductive bridging through the formerly high-conductive matrix. This situation with low-conductivity between the electrodes 5a and 5b represents the OFF state of the film 7.

While certain exemplary embodiments have been described in detail and shown in the accompanying drawings, it is to be understood that such embodiments are merely illustrative of and not restrictive to the scope invention. It will thus be recognized that various modifications may be made to the illustrated and other embodiments of the invention, without departing from the scope and spirit of the invention as defined by the appended claims.

What is claimed is:

1. CBRAM memory cell comprising a matrix host material (7) and metallic material (10) incorporated or deposited therein, the memory cell (4) exhibiting a memory switching mechanism,
characterised in,
that the memory switching mechanism is substantially based on a variation of the concentration of the metallic material (10) incorporated or deposited in the matrix host material (7).

2. CBRAM memory cell according to claim 1, wherein the resistive switching mechanism of the CBRAM memory cell is based on statistical bridging of multiple metal rich precipitates or clusters (10) formed by the metallic material incorporated or deposited in the matrix host material (7).

3. CBRAM memory cell according to claim 1, wherein the matrix host material (7) comprises a chalcogenide material, e.g. GeSe—, GeS—, Si—Se, Si—S, Si—Ge—Se, Si—Ge—S, Ge—Se—S, Si—Se—S, W—O AgSe—, Ag—S, CuS—, or combinations thereof and the metallic material (10) incorporated or deposited in the matrix host material (7) comprises silver, copper, gold, zinc, aluminum, gallium, lithium, magnesium, sodium, boron.

4. CBRAM memory cell exhibiting a resistive switching effect offering the possibility to store multiple memory states in one cell by programming said memory cell (4) to different resistance levels including at least a first memory state with a high resistance level representing a low-conductivity state of the memory cell (4) and one memory state with a low resistance level representing a high-conductivity state of the memory cell (4), characterised in,
that the resistive switching effect is substantially based on a variation of the concentration of the metallic material (10) incorporated or deposited in the matrix host material (7).

5. CBRAM memory cell according to claim 4, wherein the resistive switching mechanism of the memory cell (4) is based on a change of the electrical resistivity of the matrix host material (7) caused by local variations of the chemical composition on a nanoscale structure of the matrix host material (7).

6. CBRAM memory cell according to claim 5, wherein the metallic material (10) is incorporated or deposited in the matrix host material (7) apart from their thermal equilibrium condition.

7. CBRAM memory cell according to claim 6, wherein the matrix host material (7) comprises a variable amount of metallic material (10) atoms together with cluster-like amorphous or nanocrystalline aggregates.

8. CBRAM memory cell according to claim 7, wherein the variation of the total amount of metallic material (10) atoms being present in matrix host material (7) enabling a fast modification of the physical and especially of the electric properties of the memory cell (4).

9. CBRAM memory cell according to claim 8, wherein the incorporation or deposition of the metallic material (10) atoms being present in matrix host material (7) is being attained by a doping method, preferably UV light stimulated doping, thermal doping, implantation or electrical forming.

10. CBRAM memory cell according to claim 9, wherein up to 70% of the metallic material (10) is incorporated or deposed into the matrix host material (7).

11. CBRAM memory cell according to claim 10, wherein the nanostructure of the host matrix material is heterogeneous, in particular with respect to the chemical composition and/or the electric properties of the host matrix material (7).

12. CBRAM memory cell according to claim 11, wherein due to a voltage or current pulse with respective intensity and duration applied to the CBRAM memory cell (4) said metal rich precipitates or clusters (10) grow in size and/or density reducing the distance between said metal rich precipitates or clusters (10) until they eventually touch each other, forming an electrically conductive bridge through the matrix host material (7) of the memory cell (4) causing a change of the electrical conductivity of the memory cell (4).

13. CBRAM memory cell according to claim 12, wherein the electrically conductive bridge through the matrix host material of the memory cell (4) changes from one switching event to the next via different nanostructural metal rich precipitations or clusters (10) formed by the metallic material incorporated or deposited in the matrix host material (7).

14. CBRAM memory cell according to claim 13, wherein said resistive switching mechanism can be sustained for long storing times, so that a non-volatile memory state can be achieved.

15. CBRAM memory cell according to claim 14, wherein metallic, semiconducting, and/or ionic constituents are present in the host matrix material of the memory cell (4), which can move in the matrix host material (7), the movement of the metallic, semiconducting, and/or ionic constituents can be stimulated preferably by applying an external electric field to the matrix (7), so that an electrically induced drift of the metallic, semiconducting, and/or ionic constituents occurs.

16. CBRAM memory cell according to claim 15, wherein due to said electrically induced drift of the metallic, semiconducting, and/or ionic constituents reversible concentration changes of the metallic material (10) incorporated or deposed into the matrix host material (7) are obtained by driving in and pulling out mobile metallic, semiconducting, and/or ionic constituents into or from the matrix host material (7), respectively.

17. CBRAM memory cell according to claim 16, wherein due to the mobility of said metallic or ionic components an increase or a decrease in size and/or density of said metal rich precipitates or clusters (10) of the metallic material in the matrix host material (7) occurs.

18. CBRAM memory cell according to claim 17, wherein the matrix host material (7) of the memory cell (4) is in direct contact with a first and second electrode (5a, 5b).

19. CBRAM memory cell according to claim 18, wherein the memory cell is in electrical contact to a first electrode (5a) comprising a semiconducting or a metallic material, which does not have a significant solubility nor a significant mobility to penetrate into or mix up with the matrix host material (7) of the memory cell (4).

20. CBRAM memory cell according to claim 19, wherein the memory cell (4) is in electrical contact to a second electrode (5b) comprising a semiconducting or a metallic material with the required solubility and mobility to penetrate into or mix up with the matrix host material (7) of the memory cell (4).

21. CBRAM memory cell according to claim 20, wherein at least one electrode is in direct contact to other conducting or semiconducting materials, e.g. metal wires or metal plugs, to electrically connect the memory cell to other devices, e.g. transistors or other memory cells.

22. CBRAM memory cell according to claim 21, wherein the memory cell (4) is electrically connected to the Source/Drain region of a select transistor, which is preferably used for selecting one or more CBRAM memory cells (4) by activating the wordline of the transistor and thus passing a read/write/erase current through said Source/Drain region.

23. Memory system or memory component comprising a CBRAM cell (4) according to one of the preceding claims.

24. Computer system, comprising:
a memory component (3) with a CBRAM cell (4) according to one of the preceding claims, and
a controller (2) being adapted to operate the memory component (3) in one of several possible modes.

25. CBRAM cell according to one of the preceding claims wherein a number of memory cells (4) are arranged in a matrix array or in a matrix array including a diode.

26. A process for controlling a memory component including a CBRAM cell (4) according to one of the preceding claims, comprising the step of using various operation modes to operate the CBRAM cell (4), in particular an operation mode for long data retention, or an operation mode for fast switching between different memory states of said memory cell (4).
